(19) United States
(12) Patent Application Publication
(10) Pub. No.: US 2026/0324363 A1
(43) Pub. Date: Oct. 15, 2026

(54) MEMBER FOR SEMICONDUCTOR MANUFACTURING EQUIPMENT

(71) Applicant: NGK Corporation, Nagoya-shi (JP)

(72) Inventors: Masaki ISHIKAWA, Handa-shi (JP); Ikuhisa MORIOKA, Handa-shi (JP); Hiroya SUGIMOTO, Chiryu-shi (JP); Hiroki AKAHANE, Handa-shi (JP)

(21) Appl. No.: 19/697,959

(22) Filed: Jun. 4, 2026

Related U.S. Application Data
(63) Continuation of application No. PCT/JP2025/013824, filed on Apr. 4, 2025.

(30) Foreign Application Priority Data
May 28, 2024 (JP) 2024-086582

(51) Int. Cl. H10P 72/76

(52) U.S. Cl. CPC H10P 72/7616; H10P 72/7611

(57) ABSTRACT

A member for semiconductor manufacturing equipment includes a ceramic substrate, the ceramic substrate including an upper surface having a plurality of protrusions for placing a wafer thereon and a side wall forming an outer edge of the upper surface, wherein an arithmetic mean roughness Ra₁ of a surface of the side wall is 0.4 μm or less.

### CROSS REFERENCE TO RELATED APPLICATIONS

This application is a continuation application of PCT/JP2025/013824 filed on Apr. 4, 2025, which claims the benefit of priority of Japanese Patent Application No. 2024-086582 filed on May 28, 2024, the entire contents of which are incorporated herein by reference.

### FIELD OF THE INVENTION

The present invention is related to a member for semiconductor manufacturing equipment.

### BACKGROUND OF THE INVENTION

Conventionally, members for semiconductor manufacturing equipment used for holding, temperature control, transporting, or the like of wafers have been known. These types of members for semiconductor manufacturing equipment are also called a wafer placement table, an electrostatic chuck, a susceptor, or the like. Generally, they have the function of applying electrical power for electrostatic adsorption to an internal electrode and adsorbing a wafer using electrostatic force. Some members are known that have a function of controlling the temperature of the wafer by flowing gas between the wafer placement surface and the wafer to be adsorbed. During wafer processing, a cooling gas such as helium gas is introduced to the back surface of the wafer through the gas flow passage.

A member for semiconductor manufacturing equipment generally includes a ceramic substrate having an upper surface on which a wafer is to be placed. In addition, the upper surface for placing a wafer thereon is provided with a plurality of protrusions for supporting the wafer. Further, the ceramic substrate may also have side wall that forms the outer edge of the upper surface for placing a wafer thereon, and may further have an upper surface on which a focus ring can be placed, located on the outer peripheral side of the upper surface for placing a wafer thereon and at a lower position than the upper surface, for the purpose of improving within-wafer uniformity (Patent Literature 1).

### PRIOR ART

### Patent Literature

[Patent Literature 1] Japanese Patent Application Publication No. 2023-27641

### SUMMARY OF THE INVENTION

The upper and side surfaces of the ceramic substrate are exposed to the plasma and are susceptible to the plasma damage during wafer processing, which may cause ceramic particles that make up the side wall to shed. Further, ceramic particles may also shed due to fluorination of alumina caused by fluorine-based corrosive gases. In addition, ceramic particles may also shed due to fluorination of alumina caused by fluorine-based corrosive gases. Even when a focus ring is mounted, a gap is often provided between the focus ring and the wafer to prevent the focus ring from interfering with the wafer. In the gap, a side wall that forms a step between the upper surface for placing a wafer thereon and the upper surface on which a focus ring can be placed is exposed to the plasma side, and therefore, the side wall is affected by plasma and corrosive gases during wafer processing. When ceramic particles shed, they adhere to the wafer as particles, which can affect the semiconductor quality and reduce the yield.

Accordingly, an object of the present invention in one embodiment is to provide a member for semiconductor manufacturing equipment that comprises a ceramic substrate having an upper surface for placing a wafer thereon and a side wall that forms the outer edge of the upper surface, the member being capable of suppressing particle generation. Further, an object of the present invention in another embodiment is to provide a semiconductor manufacturing equipment component comprising a ceramic substrate having an upper surface for placing a wafer thereon, an upper surface on which a focus ring can be placed, and a side wall defining a step between the two upper surfaces, the member being capable of suppressing particle generation.

The present inventors have conducted extensive research to solve the above problems and have created the present invention, which is exemplified as below.

### [Aspect 1]

A member for semiconductor manufacturing equipment comprising a ceramic substrate, the ceramic substrate comprising: an upper surface having a plurality of protrusions for placing a wafer thereon; and a side wall forming an outer edge of the upper surface, wherein an arithmetic mean roughness Ra₁ of a surface of the side wall is 0.4 μm or less.

### [Aspect 2]

The member for semiconductor manufacturing equipment according to aspect 1, wherein the surface of the side wall has patterned irregularities.

### [Aspect 3]

The member for semiconductor manufacturing equipment according to aspect 2, wherein the patterned irregularities are formed by laser processing.

### [Aspect 4]

The member for semiconductor manufacturing equipment according to aspect 2 or 3, wherein the surface of the side wall has one or more of the following patterned irregularities i) to iv):
i) A pattern composed of a plurality of streak-like convex portions
ii) A pattern composed of a plurality of dot-like convex portions
iii) A pattern composed of a plurality of dimples
iv) A pattern composed of mesh-like convex portions in which a plurality of linear convex portions intersect.

### [Aspect 5]

The member for semiconductor manufacturing equipment according to any one of aspects 1 to 4, wherein the upper surface and the side wall are connected via a chamfered portion, and an arithmetic mean roughness Ra₄ of the surface of the chamfered portion is 0.4 μm or less.

### [Aspect 6]

The member for semiconductor manufacturing equipment according to any one of aspects 1 to 5, wherein either or both of the following are satisfied:
an arithmetic mean height Sa₁ of the surface of the side wall is 1.1 μm or less;
a valley void volume Vᵥᵥ₁ of the surface of the side wall is 0.5 ml/m² or less.

### [Aspect 7]

The member for semiconductor manufacturing equipment according to aspect 5, wherein either or both of the following are satisfied:
an arithmetic mean height Sa₄ of the surface of the chamfered portion is 1.1 μm or less;
a valley void volume Vᵥᵥ₄ of the surface of the chamfered portion is 0.5 ml/m² or less.

### [Aspect 8]

The member for semiconductor manufacturing equipment according to any one of aspects 1 to 7, wherein either or both of the following are satisfied:
a standard deviation of the arithmetic mean height Sa₁ of the surface of the side wall is 0.1 μm or less;
a standard deviation of the valley void volume Vᵥᵥ₁ of the surface of the side wall is 0.1 ml/m² or less.

### [Aspect 9]

The member for semiconductor manufacturing equipment according to aspect 5 or 7, wherein either or both of the following are satisfied:
a standard deviation of the arithmetic mean height Sa₄ of the surface of the chamfered portion is 0.1 μm or less;
a standard deviation of the valley void volume V_{wv4} of the surface of the chamfered portion is 0.1 ml/m² or less.

### [Aspect 10]

The member for semiconductor manufacturing equipment according to any one of aspects 1 to 9, wherein the arithmetic mean roughness Ra₁ of the surface of the side wall is smaller when measured in a circumferential direction of the ceramic substrate than when measured in a thickness direction of the ceramic substrate.

### [Aspect 11]

The member for semiconductor manufacturing equipment according to any one of aspects 1 to 10, wherein at least a portion of the side wall is covered with a coating layer, and a porosity of the coating layer is 2% or less.

### [Aspect 12]

A member for semiconductor manufacturing equipment comprising a ceramic substrate, the ceramic substrate comprising:
a central portion upper surface having a plurality of protrusions for placing a wafer thereon;
an outer peripheral portion upper surface located on an outer peripheral side of the central portion upper surface and lower than the central portion upper surface; and
a central portion side wall defining a step between the central portion upper surface and the outer peripheral portion upper surface;
wherein an arithmetic mean roughness Ra₁ of a surface of the central portion side wall is smaller than an arithmetic mean roughness Ra₂ of the outer peripheral portion upper surface.

### [Aspect 13]

The member for semiconductor manufacturing equipment according to aspect 12, wherein the arithmetic mean roughness Ra₁ of the surface of the central portion side wall is greater than an arithmetic mean roughness Ra₃ of an upper end surface of the plurality of protrusions.

### [Aspect 14]

The member for semiconductor manufacturing equipment according to aspect 12 or 13, wherein the arithmetic mean roughness Ra₁ of the surface of the central portion side wall is 0.4 μm or less.

### [Aspect 15]

The member for semiconductor manufacturing equipment according to any one of aspects 12 to 14, wherein the central portion upper surface and the central portion side wall are connected via a chamfered portion.

### [Aspect 16]

The member for semiconductor manufacturing equipment according to aspect 15, wherein an arithmetic mean roughness Ra₄ of a surface of the chamfered portion is smaller than the arithmetic mean roughness Ra₂ of the outer peripheral portion upper surface.

### [Aspect 17]

The member for semiconductor manufacturing equipment according to aspect 15 or 16, wherein an arithmetic mean roughness Ra₄ of a surface of the chamfered portion is greater than an arithmetic mean roughness Ra₃ of an upper end surface of the plurality of protrusions.

### [Aspect 18]

The member for semiconductor manufacturing equipment according to any one of aspects 15 to 17, wherein an arithmetic mean roughness Ra₄ of a surface of the chamfered portion is 0.4 μm or less.

### [Aspect 19]

The member for semiconductor manufacturing equipment according to any one of aspects 15 to 18, wherein an absolute value of a difference between an arithmetic mean roughness Ra₄ of a surface of the chamfered portion and the arithmetic mean roughness Ra₁ of the surface of the central portion side wall is 0.4 μm or less.

### [Aspect 20]

The member for semiconductor manufacturing equipment according to any one of aspects 12 to 19, wherein the surface of the central portion side wall has patterned irregularities.

### [Aspect 21]

The member for semiconductor manufacturing equipment according to aspect 20, wherein the patterned irregularities are formed by laser processing.

### [Aspect 22]

The member for semiconductor manufacturing equipment according to aspect 20 or 21, wherein the surface of the central portion side wall has one or more patterned irregularities selected from the following i) to iii):
i) A pattern composed of a plurality of dot-like convex portions
ii) A pattern composed of a plurality of dimples
iii) A pattern composed of mesh-like convex portions in which a plurality of linear convex portions intersect.

### [Aspect 23]

The member for semiconductor manufacturing equipment according to any one of aspects 20 to 22, wherein the arithmetic mean roughness Ra₁ of the surface of the central portion side wall is 0.4 μm or less.

### [Aspect 24]

The member for semiconductor manufacturing equipment according to any one of aspects 12 to 23, wherein at least a portion of the central portion side wall is covered with a coating layer, and a porosity of the coating layer is 2% or less.

### [Aspect 25]

A member for semiconductor manufacturing equipment comprising a ceramic substrate, the ceramic substrate comprising: an upper surface having a plurality of protrusions for placing a wafer thereon; and a side wall forming an outer edge of the upper surface, wherein an arithmetic mean height Sa₁ of a surface of the side wall is 1.1 μm or less.

### [Aspect 26]

The member for semiconductor manufacturing equipment according to aspect 25, wherein the upper surface and the side wall are connected via a chamfered portion, and an arithmetic mean height Sa₄ of a surface of the chamfered portion is 1.1 μm or less.

### [Aspect 27]

The member for semiconductor manufacturing equipment according to aspect 25 or 26, wherein a standard deviation of the arithmetic mean height Sa₁ of the surface of the side wall is 0.1 μm or less.

### [Aspect 28]

The member for semiconductor manufacturing equipment according to aspect 26, or aspect 27 dependent on aspect 26, wherein a standard deviation of the arithmetic mean height Sa₄ of the surface of the chamfered portion is 0.1 μm or less.

### [Aspect 29]

The member for semiconductor manufacturing equipment according to any one of aspects 25 to 28, wherein at least a portion of the side wall is covered with a coating layer, and a porosity of the coating layer is 2% or less.

A member for semiconductor manufacturing equipment according to one embodiment of the present invention comprises a ceramic substrate that is less likely to generate particles even if its side wall is affected by plasma. A member for semiconductor manufacturing equipment according to another embodiment of the present invention comprises a ceramic substrate that is less likely to generate particles due to the influence of plasma even if plasma enters a gap provided between a focus ring and a wafer. Therefore, the member for semiconductor manufacturing equipment can contribute to improving the stability of semiconductor quality and improving yield.

### BRIEF DESCRIPTION OF THE DRAWINGS

FIG. 1-1 is a schematic partial vertical cross-sectional view of a member for semiconductor manufacturing equipment according to a first embodiment of the present invention (a partial cross-sectional view when cut along a plane including the central axis of the member for semiconductor manufacturing equipment).

FIG. 1-2 is a schematic partial enlarged view of the vicinity of the portion enclosed by the thick-lined box shown in FIG. 1-1.

FIG. 1-3 is a schematic plan view of a ceramic substrate according to a first embodiment of the present invention.

FIG. 2-1 is a schematic partial vertical cross-sectional view of a member for semiconductor manufacturing equipment according to a second embodiment of the present invention (a partial cross-sectional view when cut along a plane including the central axis of the member for semiconductor manufacturing equipment).

FIG. 2-2 is a schematic partial enlarged view of the vicinity of the portion enclosed by the thick-lined box shown in FIG. 2-1.

FIG. 2-3 is a schematic plan view of a ceramic substrate according to a second embodiment of the present invention.

FIG. 3 shows an example of patterned irregularities provided on the surface of a side wall.

FIGS. 4A to 4F are manufacturing process diagrams of a member for semiconductor manufacturing equipment according to a second embodiment of the present invention.

### DETAILED DESCRIPTION OF THE INVENTION

Hereinafter, embodiments of the present invention will now be described in detail with reference to the drawings. It should be understood that the present invention is not intended to be limited to the following embodiments, and any change, improvement or the like of the design may be appropriately added based on common general knowledge of those skilled in the art without departing from the spirit of the present invention. In addition, as used herein, “upper” and “lower” are used for convenience to express the relative positional relationship when a member for semiconductor manufacturing equipment is placed on a horizontal plane with a ceramic substrate facing upward, and they do not represent any absolute positional relationships. Therefore, depending on the orientation of the member for semiconductor manufacturing equipment, “upper” and “lower” may become “lower” and “upper”, or “left” and “right”, or “front” and “rear”.

### <1. Configuration of Member for Semiconductor Manufacturing Equipment>

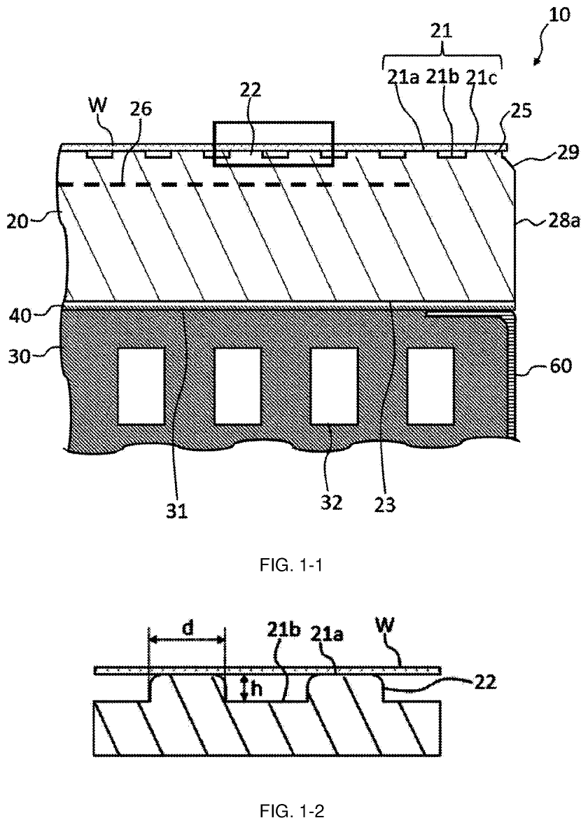

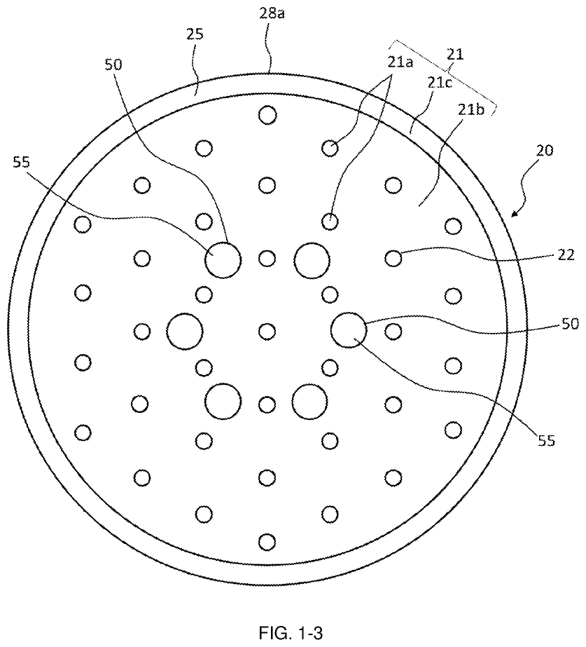

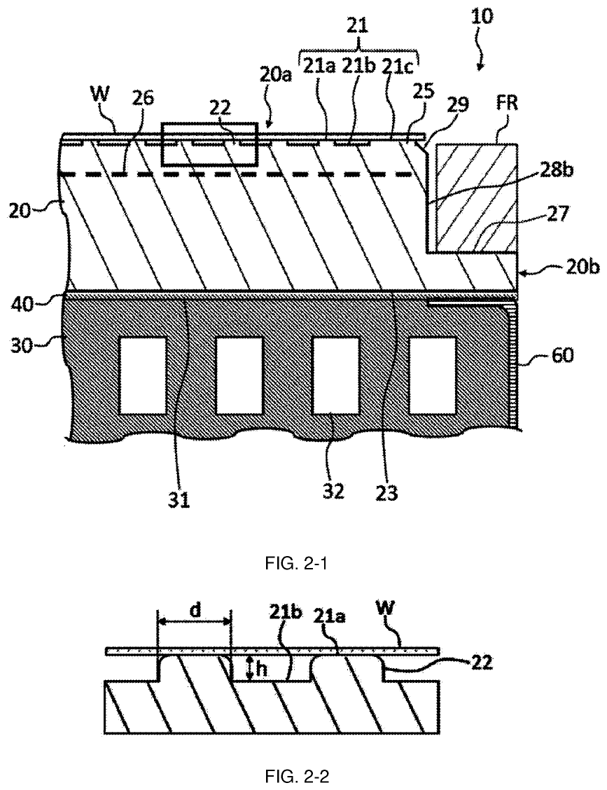

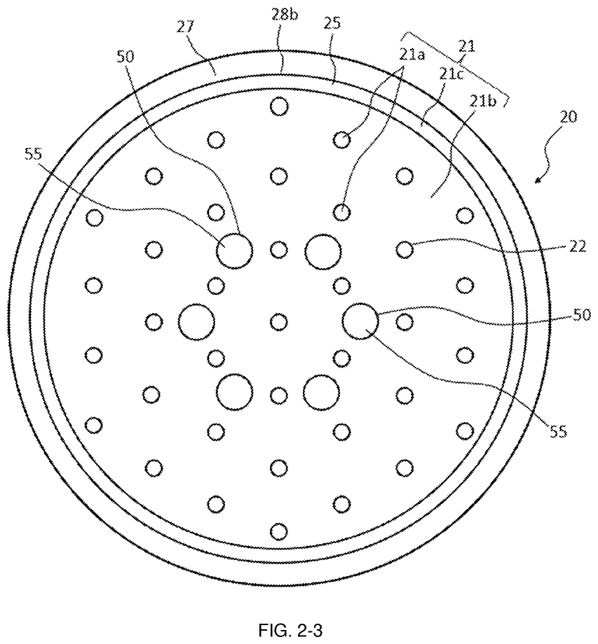

Referring to the partial vertical cross-sectional views shown in FIGS. 1-1 and 2-1, the member 10 for a semiconductor manufacturing equipment according to the first and second embodiments of the present invention can be used when performing processes such as CVD and etching on a wafer W using plasma. The member 10 for a semiconductor manufacturing equipment according to the first and second embodiments comprises a ceramic substrate 20 having an upper surface 21 on which a wafer W can be placed, a lower surface 23, and a built-in electrode 26. Further, the member 10 for a semiconductor manufacturing equipment according to the first and second embodiments comprises a base plate 30 located on the lower surface 23 side of the ceramic substrate 20 and incorporating a refrigerant flow path 32. The ceramic substrate 20 and the base plate 30 can be bonded via a bonding layer 40.

The ceramic substrate 20 of the member 10 for a semiconductor manufacturing equipment according to the first embodiment includes an upper surface 21 that is circular in a plan view and the side wall 28a that forms the outer edge of the upper surface 21. The ceramic substrate 20 may have a diameter of 300 to 400 mm and a thickness of 1 to 6 mm, for example. A wafer W may be placed on the upper surface 21.

The ceramic substrate 20 of the member 10 for a semiconductor manufacturing equipment according to the second embodiment has a central portion 20a having a circular upper surface 21 in a plan view, and an outer peripheral portion 20b having an annular upper surface 27 in a plan view on the outer peripheral side of the central portion 20a. The central portion 20a of the ceramic substrate 20 may have a diameter of 300 to 400 mm and a thickness of 1 to 6 mm, for example. A wafer W can be placed on the upper surface 21 of the central portion 20a, and a focus ring can be placed on an upper surface 27 of the outer peripheral portion 20b. Hereinafter, the focus ring may be abbreviated as “FR.” A step formed by the side wall 28b of the central portion 20a is provided between the upper surface 21 of the central portion 20a and the upper surface 27 of the outer peripheral portion 20b, so that the upper surface 27 of the outer peripheral portion 20b is located lower than the upper surface 21 of the central portion 20a. The height (step) of the side wall 28b may be, for example, 0.5 to 5 mm. The lower surfaces 23 of the central portion 20a and the outer peripheral portion 20b may be flush with each other.

The upper surface 21 of the ceramic substrate 20 of the first embodiment and the upper surface 21 of the central portion 20a of the ceramic substrate 20 of the second embodiment are provided with a plurality of protrusions 22 for placing a wafer W thereon. In addition, a seal band 25 may be formed along the outer edge of the upper surface 21. In this case, the wafer W may be supported by the upper end surface 21c of the seal band 25 and the upper end surfaces 21a of the plurality of protrusions 22. It is preferable that the seal band 25 and the plurality of protrusions 22 are at the same height. As shown in FIGS. 1-3 and 2-3, in one embodiment, an annular seal band 25 is formed along the outer edge of the upper surface 21 of the ceramic substrate 20, and a plurality of protrusions 22 are formed over the entire surface inside the seal band 25.

In the ceramic substrate 20 of the first embodiment, smoothing the surface of the side wall 28a is effective in suppressing particle shedding. This is because smoothing reduces the number of microscopic protrusions that are prone to breakage. Further, slurry used in processing during the manufacturing process and processing residues accumulate in the micro-recesses, becoming a source of particles. Therefore, it is preferable to polish the surface of the side wall 28a to make it smooth. Polishing is also expected to suppress the formation of fractured layer and microcracks in ceramics. More specifically, it is desirable to smooth the surface of the side wall 28a to such an extent that the fractured layer that is the starting point for particle shedding is removed from the surface of the side wall 28a. The fractured layer is a fragile surface layer with irregularities and cracks that occur during machining, so removing the fractured layer and leaving the surface smooth can further reduce the risk of particle shedding. As an indicator that the fractured layer has been removed, the arithmetic mean roughness Ra₁ of the surface of the side wall 28a is preferably 0.4 μm or less, more preferably 0.3 μm or less, and even more preferably 0.1 μm or less. Although no particular lower limit is set for the arithmetic mean roughness Ra₁ of the surface of the side wall 28a, from the viewpoint of cost-effectiveness, it is preferable that it be 0.05 μm or more. Therefore, the arithmetic mean roughness Ra₁ of the surface of the side wall 28a is preferably, for example, 0.05 to 0.4 μm, more preferably 0.05 to 0.3 μm, and even more preferably 0.05 to 0.1 μm.

The preferred range of the arithmetic mean roughness Ra₁ of the surface of the side wall 28a should be satisfied regardless of the measurement direction. However, from the viewpoint of suppressing particles, it is preferable that the arithmetic mean roughness Ra₁ of the surface of the side wall 28a is smaller when measured in the circumferential direction of the ceramic substrate 20 than when measured in the thickness direction of the ceramic substrate 20.

Further, in addition to the arithmetic mean roughness Ra₁, which is a line roughness parameter, the smoothness of the surface of the side wall 28a can also be discussed using the arithmetic mean height Sa₁ and the valley void volume Vᵥᵥ₁, which are surface roughness parameters. In this case, as an indicator of whether the fractured layer has been removed, it is preferable that either or both of the following be satisfied: the arithmetic mean height Sa₁ of the surface of the side wall 28a is 1.1 μm or less; the valley void volume Vᵥᵥ₁ of the of the surface of the side wall 28a is 0.5 ml/m² or less.

It is more preferable that either or both of the following be satisfied: the arithmetic mean height Sa₁ of the surface of the side wall 28a is 0.6 μm or less; the valley void volume Vᵥᵥ₁ of the surface of the side wall 28a is 0.2 ml/m² or less.

It is even more preferable that either or both of the following be satisfied: the arithmetic mean height Sa₁ of the surface of the side wall 28a is 0.2 μm or less; the valley void volume Vᵥᵥ₁ of the surface of the side wall 28a is 0.1 ml/m² or less.

Although no particular lower limit is set for the arithmetic mean height Sa₁ of the surface of the side wall 28a and the valley void volume Vᵥᵥ₁ of the surface of the side wall 28a, from the viewpoint of cost-effectiveness, it is preferable that either or both of the following be satisfied: the arithmetic mean height Sa₁ of the surface of the side wall 28a is 0.05 μm or more; the valley void volume Vᵥᵥ₁ of the surface of the side wall 28a is 0.01 ml/m² or more.

Therefore, for example, it is preferable that either or both of the following be satisfied: the arithmetic mean height Sa₁ of the surface of the side wall 28a is 0.05 to 1.1 μm; the valley void volume Vᵥᵥ₁ of the surface of the side wall 28a is 0.01 to 0.5 ml/m².

It is more preferable that either or both of the following be satisfied: the arithmetic mean height Sa₁ of the surface of the side wall 28a is 0.05 to 0.6 μm; the valley void volume Vᵥᵥ₁ of the surface of the side wall 28a is 0.01 to 0.2 ml/m².

It is even more preferable that either or both of the following be satisfied: the arithmetic mean height Sa₁ of the surface of the side wall 28a is 0.05 to 0.2 μm; the valley void volume Vᵥᵥ₁ of the surface of the side wall 28a is 0.01 to 0.1 ml/m².

From the viewpoint of quality stability, it is desirable that the surface of the side wall 28a be uniformly smooth. Therefore, for example, it is preferable that either or both of the following be satisfied: the standard deviation of the arithmetic mean height Sa₁ of the surface of the side wall 28a is 0.1 μm or less; the standard deviation of the valley void volume Vᵥᵥ₁ of the surface of the side wall 28a is 0.1 ml/m² or less.

It is more preferable that either or both of the following be satisfied: the standard deviation of the arithmetic mean height Sa₁ of the surface of the side wall 28a is 0.02 μm or less; the standard deviation of the valley void volume Vᵥᵥ₁ of the surface of the side wall 28a is 0.03 ml/m² or less.

It is even more preferable that either or both of the following be satisfied: the standard deviation of the arithmetic mean height Sa₁ of the surface of the side wall 28a is 0.005 μm or less; the standard deviation of the valley void volume Vᵥᵥ₁ of the surface of the side wall 28a is 0.02 ml/m² or less.

Although no particular lower limit is set for the standard deviation of the arithmetic mean height Sa₁ of the surface of the side wall 28a and the standard deviation of the valley void volume Vᵥᵥ₁ of the surface of the side wall 28a, from the viewpoint of cost-effectiveness, it is preferable that either or both of the following be satisfied: the standard deviation of the arithmetic mean height Sa₁ of the surface of the side wall 28a is 0.001 μm or more; the standard deviation of the valley void volume Vᵥᵥ₁ of the surface of the side wall 28a is 0.001 ml/m² or more.

Therefore, for example, it is preferable that either or both of the following be satisfied: the standard deviation of the arithmetic mean height Sa₁ of the surface of the side wall 28a is 0.001 to 0.1 μm; the standard deviation of the valley void volume Vᵥᵥ₁ of the surface of the side wall 28a is 0.001 to 0.1 ml/m².

It is more preferable that either or both of the following be satisfied: the standard deviation of the arithmetic mean height Sa₁ of the surface of the side wall 28a is 0.001 to 0.02 μm; the standard deviation of the valley void volume Vᵥᵥ₁ of the surface of the side wall 28a is 0.001 to 0.03 ml/m².

It is even more preferable that either or both of the following be satisfied: the standard deviation of the arithmetic mean height Sa₁ of the surface of the side wall 28a is 0.001 to 0.005 μm; the standard deviation of the valley void volume Vᵥᵥ₁ of the surface of the side wall 28a is 0.001 to 0.02 ml/m².

The same can be said for the ceramic substrate 20 of the second embodiment. Normally, the side wall 28b of the central portion 20a of the ceramic substrate 20 of the second embodiment and the upper surface 27 of the peripheral portion 20b are both formed by machining such as cutting. Unless particular polishing is performed after machining, the side wall 28b of the central portion 20a and the upper surface 27 of the outer peripheral portion 20b have the same degree of surface roughness. It is preferable that the ceramic particles that make up the side wall 28b of the central portion 20a be made difficult to shed when affected by plasma. To prevent the ceramic particles from shedding, it is effective to make the surface of the side wall 28b smooth. This is because smoothing reduces the number of microscopic protrusions that are prone to breakage. On the other hand, since the upper surface 27 of the outer peripheral portion 20b is a mounting surface for the focus ring and it is protected by the focus ring, there is little need to smooth it. Also, from the viewpoint of manufacturing costs, it is desirable not to perform unnecessary polishing on the upper surface 27 of the outer peripheral portion 20b.

Therefore, when polishing is performed to smooth the surface of the side wall 28b of the central portion 20a, the arithmetic mean roughness Ra₁ of the surface of the side wall 28b of the central portion 20a becomes smaller than the arithmetic mean roughness Ra₂ of the upper surface 27 of the outer peripheral portion 20b. More specifically, it is desirable to smooth the surface of the side wall 28b to such an extent that the fractured layer that is the starting point for particle shedding is removed from the surface of the side wall 28a. The fractured layer is a fragile surface layer with irregularities and cracks that occur during machining, so removing the fractured layer and leaving the surface smooth can further reduce the risk of particle shedding. As an indicator that the fractured layer has been removed, the arithmetic mean roughness Ra₁ of the surface of the side wall 28b of the central portion 20a is preferably 0.4 μm or less, more preferably 0.3 μm or less, and even more preferably 0.1 μm or less. Although no particular lower limit is set for the arithmetic mean roughness Ra₁ of the surface of the side wall 28b of the central portion 20a, from the viewpoint of cost-effectiveness, it is preferable that it be 0.05 μm or more. Therefore, the arithmetic mean roughness Ra₁ of the surface of the side wall 28b of the central portion 20a is, for example, preferably 0.05 to 0.4 μm, more preferably 0.05 to 0.3 μm, and even more preferably 0.05 to 0.1 μm.

The preferred range of the arithmetic mean roughness Ra₁ of the surface of the side wall 28b of the central portion 20a should be satisfied regardless of the measurement direction. However, from the viewpoint of suppressing particles, it is preferable that the arithmetic mean roughness Ra₁ of the surface of the side wall 28b of the central portion 20a is smaller when measured in the circumferential direction of the ceramic substrate 20 than when measured in the thickness direction of the ceramic substrate 20.

Further, in addition to the arithmetic mean roughness Ra₁, which is a line roughness parameter, the smoothness of the surface of the side wall 28b of the central portion 20a can also be discussed using the arithmetic mean height Sa₁ and the valley void volume Vᵥᵥ₁, which are surface roughness parameters. Therefore, when polishing is performed to smooth the surface of the side wall 28b of the central portion 20a, the arithmetic mean height Sa₁ of the surface of the side wall 28b of the central portion 20a becomes smaller than the arithmetic mean height Sa₂ of the upper surface 27 of the outer peripheral portion 20b, and the valley void volume Vᵥᵥ₁ of the surface of the side wall 28b of the central portion 20a becomes smaller than the valley void volume Vᵥᵥ₂ of the upper surface 27 of the outer peripheral portion 20b. As an indicator that the fractured layer has been removed, it is preferable that either or both of the following be satisfied: the arithmetic mean height Sa₁ of the surface of the side wall 28b of the central portion 20a is 1.1 μm or less; the valley void volume Vᵥᵥ₁ of the surface of the side wall 28b of the central portion 20a is 0.5 ml/m² or less.

It is more preferable that either or both of the following be satisfied: the arithmetic mean height Sa₁ of the surface of the side wall 28b of the central portion 20a is 0.6 μm or less; the valley void volume Vᵥᵥ₁ of the surface of the side wall 28b of the central portion 20a is 0.2 ml/m² or less.

It is even more preferable that either or both of the following be satisfied: the arithmetic mean height Sa₁ of the surface of the side wall 28b of the central portion 20a is 0.2 μm or less; the valley void volume Vᵥᵥ₁ of the surface of the side wall 28b of the central portion 20a is 0.1 ml/m² or less.

Although no particular lower limit is set for the arithmetic mean height Sa₁ of the surface of the side wall 28b of the central portion 20a and the valley void volume Vᵥᵥ₁ of the surface of the side wall 28b of the central portion 20a, from the viewpoint of cost-effectiveness, it is preferable that either or both of the following be satisfied: the arithmetic mean height Sa₁ of the surface of the side wall 28b of the central portion 20a is 0.05 μm or more; the valley void volume Vᵥᵥ₁ of the surface of the side wall 28b of the central portion 20a is 0.01 ml/m² or more.

Therefore, for example, it is preferable that either or both of the following be satisfied: the arithmetic mean height Sa₁ of the surface of the side wall 28b of the central portion 20a is 0.05 to 1.1 μm; the valley void volume Vᵥᵥ₁ of the surface of the side wall 28b of the central portion 20a is 0.01 to 0.5 ml/m².

It is more preferable that either or both of the following be satisfied: the arithmetic mean height Sa₁ of the surface of the side wall 28b of the central portion 20a is 0.05 to 0.6 μm; the valley void volume Vᵥᵥ₁ of the surface of the side wall 28b of the central portion 20a is 0.01 to 0.2 ml/m².

It is even more preferable that either or both of the following be satisfied: the arithmetic mean height Sa₁ of the surface of the side wall 28b of the central portion 20a is 0.05 to 0.2 μm; the valley void volume Vᵥᵥ₁ of the surface of the side wall 28b of the central portion 20a is 0.01 to 0.1 ml/m².

From the viewpoint of quality stability, it is desirable that the surface of the side wall 28b of the central portion 20a be uniformly smooth. Therefore, for example, it is preferable that either or both of the following be satisfied: the standard deviation of the arithmetic mean height Sa₁ of the surface of the side wall 28b of the central portion 20a is 0.1 μm or less; the standard deviation of the valley void volume Vᵥᵥ₁ of the surface of the side wall 28b of the central portion 20a is 0.1 ml/m² or less.

It is more preferable that either or both of the following be satisfied: the standard deviation of the arithmetic mean height Sa₁ of the surface of the side wall 28b of the central portion 20a is 0.02 μm or less; the standard deviation of the valley void volume Vᵥᵥ₁ of the surface of the side wall 28b of the central portion 20a is 0.03 ml/m² or less.

It is even more preferable that either or both of the following be satisfied: the standard deviation of the arithmetic mean height Sa₁ of the surface of the side wall 28b of the central portion 20a is 0.005 μm or less; the standard deviation of the valley void volume Vᵥᵥ₁ of the surface of the side wall 28b of the central portion 20a is 0.002 ml/m² or less.

Although no particular lower limit is set for the standard deviation of the arithmetic mean height Sa₁ of the surface of the side wall 28b of the central portion 20a and the standard deviation of the valley void volume Vᵥᵥ₁ of the surface of the side wall 28b of the central portion 20a, from the viewpoint of cost-effectiveness, it is preferable that either or both of the following be satisfied: the standard deviation of the arithmetic mean height Sa₁ of the surface of the side wall 28b of the central portion 20a is 0.001 μm or more; the standard deviation of the valley void volume Vvv of the surface of the side wall 28b of the central portion 20a is 0.001 ml/m² or more.

Therefore, for example, it is preferable that either or both of the following be satisfied: the standard deviation of the arithmetic mean height Sa₁ of the surface of the side wall 28b of the central portion 20a is 0.001 to 0.1 μm; the standard deviation of the valley void volume Vᵥᵥ₁ of the surface of the side wall 28b of the central portion 20a is 0.001 to 0.1 ml/m².

It is more preferable that either or both of the following be satisfied: the standard deviation of the arithmetic mean height Sa₁ of the surface of the side wall 28b of the central portion 20a is 0.001 to 0.02 μm; the standard deviation of the valley void volume Vᵥᵥ₁ of the surface of the side wall 28b of the central portion 20a is 0.001 to 0.003 ml/m².

It is even more preferable that either or both of the following be satisfied: the standard deviation of the arithmetic mean height Sa₁ of the surface of the side wall 28b of the central portion 20a is 0.001 to 0.005 μm; the standard deviation of the valley void volume Vᵥᵥ₁ of the surface of the side wall 28b of the central portion 20a is 0.001 to 0.002 ml/m².

The surface of the side wall 28a of the ceramic substrate 20 of the first embodiment and the surface of the side wall 28b of the central portion 20a of the ceramic substrate 20 of the second embodiment preferably have patterned irregularities. The patterned irregularities can be formed, for example, by performing laser processing after polishing. Further, after forming a pattern by laser processing, the pattern may be mirror-finished by soft blasting. By-products flying from the inside of the chamber during wafer processing can adhere to the side walls 28a, 28b like a film. At this time, if the side walls 28a, 28b have patterned irregularities, there is an advantage that the particles that have adhered are less likely to shed due to an anchor effect. However, even when the side walls 28a, 28b have patterned irregularities, it is preferable that the surfaces of the side walls 28a, 28b satisfy the above-mentioned condition of arithmetic mean roughness. This is for the purpose of suppressing particle shedding from the surfaces of the side walls 28a, 28b.

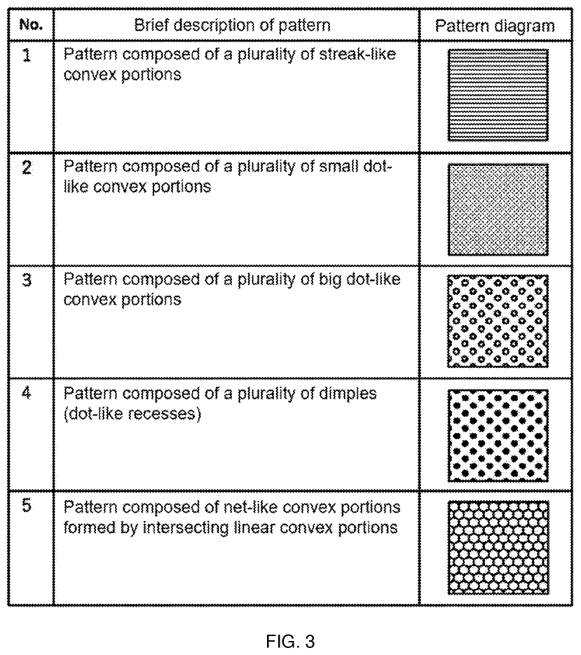

The structure of the patterned irregularities is not particularly limited, and five specific examples of the patterned irregularities on the surfaces of the side walls 28a, 28b are shown in FIG. 3.

The irregularity of No. 1 has a pattern composed of a plurality of streak-like convex portions. The line width of each streak-like convex portion can be, for example, 20 to 200 μm.

The irregularity of No. 2 has a pattern composed of a plurality of dot-like convex portions. Each dot-like convex portion in No. 2 is relatively small. It is preferable that the plurality of dot-like convex portions are arranged evenly on the surfaces of the side walls 28a, 28b. The area of each dot-like convex portion when observed from a direction perpendicular to the surface can be, for example, 200 to 25,000 μm².

The irregularity of No. 3 also has a pattern composed of a plurality of dot-like convex portions. Each dot-like convex portion in No. 3 is relatively large. It is preferable that the plurality of dot-like convex portions are arranged evenly on the surfaces of the side walls 28a, 28b. The area of each dot-like convex portion when observed from a direction perpendicular to the surface can be, for example, 2,000 to 250,000 μm². The irregularity of No. 2 and the irregularity of No. 3 differ in the area of each dot-like convex portion.

The irregularity of No. 4 has a pattern composed of a reference surface and a plurality of dimples (dot-like recesses) provided on the reference surface. It is preferable that the plurality of dimples be arranged evenly on the surfaces of the side walls 28a, 28b. The area of each dimple when observed from a direction perpendicular to the surface can be, for example, 200 to 25,000 μm².

The irregularity of No. 5 has a pattern composed of mesh-like convex portions in which a plurality of linear convex portions intersect. In the illustrated embodiment, each mesh of the mesh-like convex portion is hexagonal (honeycomb-shaped), but each mesh of the mesh-like convex portion may be other polygonal shapes such as triangles, quadrangles, pentagons, or octagons, or may be a combination of multiple polygonal shapes such as pentagons and triangles. The line width of each linear convex portion when observed from a direction perpendicular to the surface can be, for example, 20 to 200 μm. The area of each mesh when observed from a direction perpendicular to the surface can be, for example, 2,000 to 250,000 μm².

The upper surface 21 and the side wall 28a of the ceramic substrate 20 of the first embodiment are preferably connected via a chamfered portion 29. Similarly, the upper surface 21 of the central portion 20a of the ceramic substrate 20 of the second embodiment and the side wall 28b of the central portion 20 a are preferably connected via a chamfered portion 29. Chamfering the corners of the wafer mounting surface is advantageous from the viewpoint of suppressing the fracture layer at the corners and preventing particle shedding. Examples of the shape of the chamfered portion 29 include, but are not limited to, a C-chamfer and an R-chamfer. Although the chamfered portion 29 has a small area, it is a portion that may be affected by plasma during wafer processing, and it is therefore desirable to make the surface smooth. Therefore, for example, in the ceramic substrate 20 of the second embodiment, the arithmetic mean roughness Ra₄ of the surface of the chamfered portion 29 is preferably smaller than the arithmetic mean roughness Ra₂ of the upper surface 27 of the outer peripheral portion 20b. In addition, in the ceramic substrate 20 of the second embodiment, the arithmetic mean height Sa₄ of the surface of the chamfered portion 29 is preferably smaller than the arithmetic mean height Sa₂ of the upper surface 27 of the outer peripheral portion 20b. In addition, in the ceramic substrate 20 of the second embodiment, the valley void volume Vᵥᵥ₄ of the surface of the chamfered portion 29 is preferably smaller than the valley void volume Vᵥᵥ₂ of the upper surface 27 of the outer peripheral portion 20b.

In both the ceramic substrate 20 of the first embodiment and the ceramic substrate 20 of the second embodiment, the arithmetic mean roughness Ra₄ of the surface of the chamfered portion 29 is preferably 0.4 μm or less, more preferably 0.3 μm or less, and even more preferably 0.1 μm or less. Although no particular lower limit is set for the arithmetic mean roughness Ra₄ of the surface of the chamfered portion 29, from the viewpoint of cost-effectiveness, it is preferable that it be 0.05 μm or more. Therefore, the arithmetic mean roughness Ra₄ of the surface of the chamfered portion 29 is, for example, preferably 0.05 to 0.4 μm, more preferably 0.05 to 0.3 μm, and even more preferably 0.05 to 0.1 μm.

In addition, in both the ceramic substrate 20 of the first embodiment and the ceramic substrate 20 of the second embodiment, it is preferable that either or both of the following be satisfied: the arithmetic mean height Sa₄ of the surface of the chamfered portion 29 is 1.1 μm or less; the valley void volume Vᵥᵥ₄ of the surface of the chamfered portion 29 is 0.5 ml/m² or less.

It is more preferable that either or both of the following be satisfied: the arithmetic mean height Sa₄ of the surface of the chamfered portion 29 is 0.8 μm or less; the valley void volume V_{wv4} of the surface of the chamfered portion 29 is 0.2 ml/m² or less.

It is even more preferable that either or both of the following be satisfied: the arithmetic mean height Sa₄ of the surface of the chamfered portion 29 is 0.5 μm or less; the valley void volume Vᵥᵥ₄ of the surface of the chamfered portion 29 is 0.1 ml/m² or less.

Although no particular lower limit is set for the arithmetic mean height Sa₄ of the surface of the chamfered portion 29 and the valley void volume Vᵥᵥ₄ of the surface of the chamfered portion 29, from the viewpoint of cost-effectiveness, it is preferable that either or both of the following be satisfied: the arithmetic mean height Sa₄ of the surface of the chamfered portion 29 is 0.2 μm or more; the valley void volume Vᵥᵥ₄ of the surface of the chamfered portion 29 is 0.01 ml/m² or more.

Therefore, for example, it is preferable that either or both of the following be satisfied: the arithmetic mean height Sa₄ of the surface of the chamfered portion 29 is 0.2 to 1.1 μm; the valley void volume Vᵥᵥ₄ of the surface of the side wall 28a is 0.01 to 0.5 ml/m².

It is more preferable that either or both of the following be satisfied: the arithmetic mean height Sa₄ of the surface of the chamfered portion 29 is 0.2 to 0.8 μm; the valley void volume Vᵥᵥ₄ of the surface of the side wall 28a is 0.01 to 0.2 ml/m².

It is even more preferable that either or both of the following be satisfied: the arithmetic mean height Sa₄ of the surface of the chamfered portion 29 is 0.2 to 0.5 μm; the valley void volume Vᵥᵥ₄ of the surface of the side wall 28a is 0.01 to 0.1 ml/m².

From the viewpoint of quality stability, it is desirable that the surface of the chamfered portion 29 be uniformly smooth. Therefore, for example, it is preferable that either or both of the following be satisfied: the standard deviation of the arithmetic mean height Sa₄ of the surface of the chamfered portion 29 is 0.1 μm or less, and the standard deviation of the valley void volume Vᵥᵥ₄ of the surface of the chamfered portion 29 is 0.1 ml/m² or less.

It is more preferable that either or both of the following be satisfied: the standard deviation of the arithmetic mean height Sa₄ of the surface of the chamfered portion 29 is 0.02 μm or less, and the standard deviation of the valley void volume Vᵥᵥ₄ of the surface of the chamfered portion 29 is 0.03 ml/m² or less.

It is even more preferable that either or both of the following be satisfied: the standard deviation of the arithmetic mean height Sa₄ of the surface of the chamfered portion 29 is 0.005 μm or less, and the standard deviation of the valley void volume Vᵥᵥ₄ of the surface of the chamfered portion 29 is 0.02 ml/m² or less. Although no particular lower limit is set for the standard deviation of the arithmetic mean height Sa₄ of the surface of the chamfered portion 29 and the standard deviation of the valley void volume Vᵥᵥ₄ of the surface of the chamfered portion 29, from the viewpoint of cost-effectiveness, it is preferable that either or both of the following be satisfied: the standard deviation of the arithmetic mean height Sa₄ of the surface of the chamfered portion 29 is 0.001 μm or more, and the standard deviation of the valley void volume V_{wv4} of the surface of the chamfered portion 29 is 0.001 ml/m² or more.

Therefore, for example, it is preferable that either or both of the following be satisfied: the standard deviation of the arithmetic mean height Sa₄ of the surface of the chamfered portion 29 is 0.001 to 0.1 μm, and the standard deviation of the valley void volume Vᵥᵥ₄ of the surface of the chamfered portion 29 is 0.001 to 0.1 ml/m².

It is more preferable that either or both of the following be satisfied: the standard deviation of the arithmetic mean height Sa₄ of the surface of the chamfered portion 29 is 0.001 to 0.02 μm, and the standard deviation of the valley void volume V_{wv4} of the surface of the chamfered portion 29 is 0.001 to 0.03 ml/m².

It is even more preferable that either or both of the following be satisfied: the standard deviation of the arithmetic mean height Sa₄ of the surface of the chamfered portion 29 is 0.001 to 0.005 μm, and the standard deviation of the valley void volume Vᵥᵥ₄ of the surface of the chamfered portion 29 is 0.001 to 0.02 ml/m².

In this way, the level of smoothness required for the surfaces of the side walls 28a, 28b and the surface of the chamfered portion 29 is about the same. Therefore, it is convenient in terms of quality control to subject these to the same polishing process and set the surface roughness of both to the same degree. Therefore, the absolute value of the difference between the arithmetic mean roughness Ra₄ of the surface of the chamfered portion 29 and the arithmetic mean roughness Ra₁ of the surfaces of the side walls 28a, 28b is preferably 0.4 μm or less, more preferably 0.2 μm or less, and even more preferably 0.1 μm or less. The absolute value of the difference may be zero.

In addition, it is preferable that either or both of the following be satisfied: the absolute value of the difference between the arithmetic mean height Sa₄ of the surface of the chamfered portion 29 and the arithmetic mean height Sa₁ of the surfaces of the side walls 28a, 28b is 0.4 μm or less; the absolute value of the difference between the valley void volume Vᵥᵥ₄ of the surface of the chamfered portion 29 and the valley void volume Vᵥᵥ₁ of the surfaces of the side walls 28a, 28b is 0.4 ml/m² or less.

It is more preferable that either or both of the following be satisfied: the absolute value of the difference between the arithmetic mean height Sa₄ of the surface of the chamfered portion 29 and the arithmetic mean height Sa₁ of the surfaces of the side walls 28a, 28b is 0.3 μm or less; the absolute value of the difference between the valley void volume Vᵥᵥ₄ of the surface of the chamfered portion 29 and the valley void volume Vᵥᵥ₁ of the surfaces of the side walls 28a, 28b is 0.3 ml/m² or less.

It is even more preferable that either or both of the following be satisfied: the absolute value of the difference between the arithmetic mean height Sa₄ of the surface of the chamfered portion 29 and the arithmetic mean height Sa₁ of the surfaces of the side walls 28a, 28b is 0.2 μm or less; the absolute value of the difference between the valley void volume Vᵥᵥ₄ of the surface of the chamfered portion 29 and the valley void volume Vᵥᵥ₁ of the surfaces of the side walls 28a, 28b is 0.2 ml/m² or less.

The absolute value of the difference between the arithmetic mean height Sa₄ of the surface of the chamfered portion 29 and the arithmetic mean height Sa₁ of the surfaces of the side walls 28a, 28b may be 0. The absolute value of the difference between the valley void volume V_{wv4} of the surface of the chamfered portion 29 and the valley void volume Vᵥᵥ₁ of the surfaces of the side walls 28a, 28b may be 0.

FIGS. 1-2 and 2-2 show schematic structures of protrusions 22 provided on an upper surface 21 of a ceramic substrate 20 in the first and second embodiments, respectively. The shape of the protrusion 22 is not limited to, but may be, for example, a columnar shape such as a cylindrical column or a rectangular column. The height h of the protrusion 22 is, for example, 5 to 100 μm, and typically 10 to 30 μm. In addition, the diameter d of the protrusions 22 is, for example, 0.5 to 5 mm, and typically 0.5 to 3 mm. Here, the diameter d of the protrusion 22 means the equivalent circle diameter of the protrusion 22 in a plan view. In addition, the portion of the upper surface 21 of the ceramic substrate 20 on which the seal band 25 and the protrusions 22 are not provided is referred to as a reference surface 21b.

Each of the plurality of protrusions 22 has an upper end surface 21a. The wafer W in contact with the upper end surfaces 21a of the protrusions 22 may slide against the upper end surfaces 21a of the protrusions 22 due to thermal expansion or the like. In order to suppress particle shedding of ceramic particles constituting the protrusions 22 during sliding, it is desirable that the upper end surfaces 21a of the protrusions 22 be made as smooth as possible. For example, it is preferable that the arithmetic mean roughness Ra₃ of the upper end surfaces 21a of the plurality of protrusions 22 be smaller than the arithmetic mean roughness Ra₁ of the surfaces of the side walls 28a, 28b (in other words, the arithmetic mean roughness Ra₁ of the surfaces of the side walls 28a, 28b is larger than the arithmetic mean roughness Ra₃ of the upper end surfaces 21a of the plurality of protrusions 22). In addition, it is preferable that the arithmetic mean height Sa₃ of the upper end surfaces 21a of the plurality of protrusions 22 be smaller than the arithmetic mean height Sa₁ of the surfaces of the side walls 28a, 28b (in other words, the arithmetic mean height Sa₁ of the surfaces of the side walls 28a, 28b is larger than the arithmetic mean height Sa₃ of the upper end surfaces 21a of the plurality of protrusions 22). In addition, it is preferable that the valley void volume Vᵥᵥ₃ of the upper end surfaces 21a of the plurality of protrusions 22 be smaller than the valley void volume Vᵥᵥ₁ of the surfaces of the side walls 28a, 28b (in other words, the valley void volume Vᵥᵥ₁ of the surfaces of the side walls 28a, 28b is larger than the valley void volume Vᵥᵥ₃ of the upper end surfaces 21a of the plurality of protrusions 22).

Similarly, it is preferable that the arithmetic mean roughness Ra₃ of the upper end surfaces 21a of the plurality of protrusions 22 be smaller than the arithmetic mean roughness Ra₄ of the surface of the chamfered portion 29 (in other words, the arithmetic mean roughness Ra₄ of the surface of the chamfered portion 29 is larger than the arithmetic mean roughness Ra₃ of the upper end surfaces 21a of the plurality of protrusions 22). In addition, it is preferable that the arithmetic mean height Sa₃ of the upper end surfaces 21a of the plurality of protrusions 22 be smaller than the arithmetic mean height Sa₄ of the surface of the chamfered portion 29 (in other words, the arithmetic mean height Sa₄ of the surface of the chamfered portion 29 is larger than the arithmetic mean height Sa₃ of the upper end surfaces 21a of the plurality of protrusions 22). In addition, it is preferable that the valley void volume Vᵥᵥ₃ of the upper end surfaces 21a of the plurality protrusions 22 be smaller than the valley void volume Vᵥᵥ₄ of the surface of the chamfered portion 29 (in other words, the valley void volume V_{wv4} of the surface of the chamfered portion 29 is larger than the valley void volume Vᵥᵥ₃ of the upper end surfaces 21a of the plurality of protrusions 22).

Specifically, the arithmetic mean roughness Ra₃ of the upper end surfaces 21a of the plurality of protrusions 22 is preferably 0.4 μm or less, more preferably 0.2 μm or less, and even more preferably 0.1 μm or less. Although no particular lower limit is set for the arithmetic mean roughness Ra₃ of the upper end surfaces 21a of the plurality of protrusions 22, it is preferable that it be 0.05 μm or more from the viewpoint of cost-effectiveness. Therefore, the arithmetic mean roughness Ra₃ of the upper end faces 21a of the plurality of protrusions 22 is preferably 0.05 to 0.4 μm, more preferably 0.05 to 0.2 μm, and even more preferably 0.05 to 0.1 μm.

In addition, it is preferable that either or both of the following be satisfied: the arithmetic mean height Sa₃ of the upper end surfaces 21a of the plurality of protrusions 22 is 0.1 μm or less; the valley void volume Vᵥᵥ₃ of the upper end surfaces 21a of the plurality of protrusions 22 is 0.01 ml/m² or less.

It is more preferable that either or both of the following be satisfied: the arithmetic mean height Sa₃ of the upper end surfaces 21a of the plurality of protrusions 22 is 0.05 μm or less; the valley void volume Vᵥᵥ₃ of the upper end surfaces 21a of the plurality of protrusions 22 is 0.005 ml/m² or less.

It is even more preferable that either or both of the following be satisfied: the arithmetic mean height Sa₃ of the upper end surfaces 21a of the plurality of protrusions 22 is 0.03 μm or less; the valley void volume Vᵥᵥ₃ of the upper end surfaces 21a of the plurality of protrusions 22 is 0.003 ml/m² or less.

Although no particular lower limit is set for the arithmetic mean height Sa₃ of the upper end surfaces 21a of the plurality of protrusions 22 and the valley void volume Vᵥᵥ₃ of the upper end surfaces 21a of the plurality of protrusions 22, from the viewpoint of cost-effectiveness, it is preferable that either or both of the following be satisfied: the arithmetic mean height Sa₃ of the upper end surfaces 21a of the plurality of protrusions 22 is 0.01 μm or more; the valley void volume Vᵥᵥ₃ of the upper end surfaces 21a of the plurality of protrusions 22 is 0.001 ml/m² or more.

Therefore, for example, it is preferable that either or both of the following be satisfied: the arithmetic mean height Sa₃ of the upper end surfaces 21a of the plurality of protrusions 22 is 0.01 to 0.1 μm; the valley void volume Vᵥᵥ₃ of the upper end surfaces 21a of the plurality of protrusions 22 is 0.001 to 0.01 ml/m².

It is more preferable that either or both of the following be satisfied: the arithmetic mean height Sa₃ of the upper end surfaces 21a of the plurality of protrusions 22 is 0.01 to 0.05 μm; the valley void volume Vᵥᵥ₃ of the upper end surfaces 21a of the plurality of protrusions 22 is 0.001 to 0.005 ml/m².

It is even more preferable that either or both of the following be satisfied: the arithmetic mean height Sa₃ of the upper end surfaces 21a of the plurality of protrusions 22 is 0.01 to 0.03 μm; the valley void volume Vᵥᵥ₃ of the upper end surfaces 21a of the plurality of protrusions 22 is 0.001 to 0.003 ml/m².

For the same reason, the arithmetic mean roughness Ra₃ of the upper end surface 21c of the seal band 25 is preferably 0.4 μm or less, more preferably 0.2 μm or less, and even more preferably 0.1 μm or less. Although no particular lower limit is set for the arithmetic mean roughness Ra₃ of the upper end surface 21c of the seal band 25, it is preferable that it be 0.05 μm or more from the viewpoint of cost-effectiveness. Therefore, the arithmetic mean roughness Ra₃ of the upper end surface 21c of the seal band 25 is preferably 0.05 to 0.4 μm, more preferably 0.05 to 0.2 μm, and even more preferably 0.05 to 0.1 μm.

In addition, it is preferable that either or both of the following be satisfied: the arithmetic mean height Sa₃ of the upper end surface 21c of the seal band 25 is 0.1 μm or less; the valley void volume Vᵥᵥ₅ of the upper end surface 21c of the seal band 25 is 0.01 ml/m² or less.

It is more preferable that either or both of the following be satisfied: the arithmetic mean height Sa₃ of the upper end surface 21c of the seal band 25 is 0.05 μm or less; the valley void volume Vᵥᵥ₅ of the upper end surface 21c of the seal band 25 is 0.005 ml/m² or less.

It is even more preferable that either or both of the following be satisfied: the arithmetic mean height Sa₃ of the upper end surface 21c of the seal band 25 is 0.03 μm or less; the valley void volume Vᵥᵥ₅ of the upper end surface 21c of the seal band 25 is 0.003 ml/m² or less.

Although no particular lower limit is set for the arithmetic mean height Sa₃ of the upper end surface 21c of the seal band 25 and the valley void volume Vᵥᵥ₅ of the upper end surface 21c of the seal band 25, from the viewpoint of cost-effectiveness, it is preferable that either or both of the following be satisfied: the arithmetic mean height Sa₃ of the upper end surface 21c of the seal band 25 is 0.01 μm or more; the valley void volume Vᵥᵥ₅ of the upper end surface 21c of the seal band 25 is 0.001 ml/m² or more.

Therefore, for example, it is preferable that either or both of the following be satisfied: the arithmetic mean height Sa₃ of the upper end surface 21c of the seal band 25 is 0.01 to 0.1 μm; the valley void volume Vᵥᵥ₅ of the upper end surface 21c of the seal band 25 is 0.001 to 0.01 ml/m².

It is more preferable that either or both of the following be satisfied: the arithmetic mean height Sa₃ of the upper end surface 21c of the seal band 25 is 0.01 to 0.05 μm; the valley void volume Vᵥᵥ₅ of the upper end surface 21c of the seal band 25 is 0.001 to 0.005 ml/m².

It is even more preferable that either or both of the following be satisfied: the arithmetic mean height Sa₃ of the upper end surface 21c of the seal band 25 is 0.01 to 0.03 μm; the valley void volume Vᵥᵥ₅ of the upper end surface 21c of the seal band 25 is 0.001 to 0.003 ml/m².

Although the reference surface 21b of the upper surface 21 of the ceramic substrate 20 is not expected to slide against the wafer W, it may be affected by plasma during wafer processing. Therefore, it is desirable that the reference surface 21b be made smooth. Therefore, for example, in the ceramic substrate 20 according to the second embodiment, the arithmetic mean roughness Ra₃ of the reference surface 21b is preferably smaller than the arithmetic mean roughness Ra₂ of the upper surface 27 of the outer peripheral portion 20b. In addition, in the ceramic substrate 20 according to the second embodiment, the arithmetic mean height Sa₆ of the reference surface 21b is preferably smaller than the arithmetic mean height Sa₂ of the upper surface 27 of the outer peripheral portion 20b. In the ceramic substrate 20 according to the second embodiment, the valley void volume Vᵥᵥ₆ of the reference surface 21b is preferably smaller than the valley void volume Vᵥᵥ₂ of the upper surface 27 of the outer peripheral portion 20b.

In both the ceramic substrate 20 of the first embodiment and the ceramic substrate 20 of the second embodiment, the arithmetic mean roughness Ra₃ of the reference surface 21b is preferably 0.4 μm or less, more preferably 0.2 μm or less, and even more preferably 0.1 μm or less. Although no particular lower limit is set for the arithmetic mean roughness Ra₃ of the reference surface 21b, from the viewpoint of cost-effectiveness, it is preferable that it be 0.05 μm or more. Therefore, the arithmetic mean roughness Ra₃ of the reference surface 21b is, for example, preferably 0.05 to 0.4 μm, more preferably 0.05 to 0.2 μm, and even more preferably 0.05 to 0.1 μm.

In addition, in both the ceramic substrate 20 of the first embodiment and the ceramic substrate 20 of the second embodiment, it is preferable that either or both of the following be satisfied: the arithmetic mean height Sa₆ of the reference surface 21b is 0.9 μm or less; the valley void volume Vᵥᵥ₆ of the reference surface 21b is 0.2 ml/m² or less.

It is more preferable that either or both of the following be satisfied: the arithmetic mean height Sa₆ of the reference surface 21b is 0.8 μm or less; the valley void volume Vᵥᵥ₆ of the reference surface 21b is 0.15 ml/m² or less.

It is even more preferable that either or both of the following be satisfied: the arithmetic mean height Sa₃ of the reference surface 21b is 0.7 μm or less; the valley void volume Vᵥᵥ₆ of the reference surface 21b is 0.1 ml/m² or less.

Although no particular lower limit is set for the arithmetic mean height Sa₃ of the reference surface 21b and the valley void volume Vᵥᵥ₆ of the reference surface 21b, from the viewpoint of cost-effectiveness, it is preferable that either or both of the following be satisfied: the arithmetic mean height Sa₆ of the reference surface 21b is 0.05 μm or more; the valley void volume Vᵥᵥ₆ of the reference surface 21b is 0.01 ml/m² or more.

Therefore, for example, it is preferable that either or both of the following be satisfied: the arithmetic mean height Sa₆ of the reference surface 21b is 0.05 to 0.9 μm; the valley void volume Vᵥᵥ₆ of the reference surface 21b is 0.01 to 0.2 ml/m².

It is more preferable that either or both of the following be satisfied: the arithmetic mean height Sa₆ of the reference surface 21b is 0.05 to 0.8 μm; the valley void volume Vᵥᵥ₆ of the reference surface 21b is 0.01 to 0.15 ml/m².

It is even more preferable that either or both of the following be satisfied: the arithmetic mean height Sa₆ of the reference surface 21b is 0.05 to 0.7 μm; the valley void volume Vᵥᵥ₆ of the reference surface 21b is 0.01 to 0.1 ml/m².

The arithmetic mean roughness Ra₁ of the surfaces of the side walls 28a, 28b, the arithmetic mean roughness Ra₂ of the upper surface 27 of the outer circumferential portion 20b, the arithmetic mean roughness Ra₃ of the upper end surfaces 21a of the plurality of protrusions 22, the arithmetic mean roughness Ra₄ of the surface of the chamfered portion 29, the arithmetic mean roughness Ra₃ of the upper end surface 21c of the seal band 25, and the arithmetic mean roughness Ra₃ of the reference surface 21b are measured in accordance with JIS B0601: 2013, respectively. The surface roughness of each measurement point is measured at three points, and the average value is taken as the measured value.

The arithmetic mean height Sa₁ of the surfaces of the side walls 28a, 28b, the arithmetic mean height Sa₂ of the upper surface 27 of the outer circumferential portion 20b, the arithmetic mean height Sa₃ of the upper end surfaces 21a of the plurality of protrusions 22, the arithmetic mean height Sa₄ of the surface of the chamfered portion 29, the arithmetic mean height Sa₃ of the upper end surface 21c of the seal band 25, and the arithmetic mean height Sa₆ of the reference surface 21b are measured in accordance with ISO 25178, respectively, and can be measured, for example, by a non-contact roughness meter, Model VK-X3100, manufactured by Keyence Corporation. The surface roughness of each measurement point is measured at three points, and the average value is taken as the measured value.

In addition, the standard deviations of the arithmetic mean heights Sa₁, Sa₂, Sa₃, Sa₄, Sa₃ and Sa₃ are calculated based on the results of measurements taken at four locations without bias.

The valley void volume Vᵥᵥ₁ of the surfaces of the side walls 28a, 28b, the valley void volume Vᵥᵥ₂ of the upper surface 27 of the outer circumferential portion 20b, the valley void volume Vᵥᵥ₃ of the upper end surfaces 21a of the plurality of protrusions 22, the valley void volume Vᵥᵥ₄ of the surface of the chamfered portion 29, the valley void volume Vᵥᵥ₅ of the upper end surface 21c of the seal band 25, and the valley void volume Vᵥᵥ₆ of the reference surface 21b are measured in accordance with ISO 25178, respectively, and can be measured using, for example, a non-contact roughness meter, Model VK-X3100, manufactured by Keyence Corporation. The surface roughness of each measurement point is measured at three points, and the average value is taken as the measured value.

In addition, the standard deviations of the above-mentioned respective valley void volumes Vᵥᵥ₁, Vᵥᵥ₂, Vᵥᵥ₃, Vᵥᵥ₄, Vᵥᵥ₅ and Vᵥᵥ₆ are calculated based on the measurement results obtained at four locations without bias.

The ceramic substrate 20, including the protrusions 22 and the seal band 25, can be made of a ceramic material such as alumina or aluminum nitride. In a preferred embodiment, the ceramic substrate 20 contains one or two selected from alumina and aluminum nitride. In a more preferred embodiment, the ceramic substrate 20 contains 80% by mass or more of one or two selected from alumina and aluminum nitride. In an even more preferred embodiment, the ceramic substrate 20 contains 95% by mass or more of one or two selected from alumina and aluminum nitride.

The electrode 26 is a planar electrode used as an electrostatic electrode, and is connected to an external DC power source via a power supply member (not shown). The electrode 26 is formed from a material containing, for example, W, Mo, WC, MoC, or the like. A low-pass filter may be disposed midway along the power supply member. The power supply member is electrically insulated from the bonding layer 40 and the base plate 30. When a DC voltage is applied to this electrode 26, the wafer W is attracted and fixed to the wafer mounting surface, specifically, the upper end surface 21c of the seal band 25 and the upper end surfaces 21a of the protrusions 22, by electrostatic attraction, and when the application of the DC voltage is released, the attracting and fixing of the wafer W to the wafer mounting surface is released.

As the electrode 26, a heater electrode (resistance heating element) may be incorporated instead of or in addition to the electrostatic attraction electrode, or an RF electrode for generating plasma. In this case, a heater power supply is connected to the heater electrode, and an RF power supply is connected to the RF electrode. The ceramic substrate 20 may incorporate one layer of electrodes 26, or two or more layers of electrodes 26 spaced apart.

The base plate 30 may be, for example, disk-shaped. The base plate 30 may have an annular flange portion on the lower surface side that is used to clamp the member 10 for semiconductor manufacturing equipment to a jig inside the chamber. The thickness of the base plate 30 may be 10 to 30 mm, typically 15 to 30 mm. The base plate 30 is connected to a radio frequency (RF) power source and can also be used as an RF electrode.

The base plate 30 can be a disk-shaped plate (having the same diameter as or larger than the ceramic substrate 20) with good electrical and thermal conductivity. A refrigerant flow path 32 through which a refrigerant circulates may be formed inside the base plate 30. The refrigerant flowing through the refrigerant flow path 32 is preferably a liquid and is preferably electrically insulating. The electrically insulating liquid may be, for example, a fluorine-based inert liquid. The refrigerant flow path 32 can be formed, for example, in a single stroke manner from one end (inlet) to the other end (outlet) across the entire base plate 30 in a plan view. One end and the other end of the refrigerant flow path 32 are connected to a supply port and a recovery port of an external refrigerant device (not shown), respectively. The refrigerant supplied to one end of the refrigerant flow path 32 from the supply port of the external refrigerant device passes through the refrigerant flow path 32, returns from the other end of the refrigerant flow path 32 to the recovery port of the external refrigerant device, and after its temperature is adjusted, is supplied again from the supply port to one end of the refrigerant flow path 32.

The base plate 30 can be made of, for example, a metal material or a composite material of metal and ceramics. Examples of the metal material include Al, Ti, Mo, and alloys thereof, and the like. Examples of the composite material of metal and ceramic include metal matrix composites (MMC) and ceramic matrix composites (CMC), and the like. Specific examples of the composite material include materials containing Si, SiC, and Ti (also known as SiSiCTi), materials in which porous SiC is impregnated with Al and/or Si, and the composite material of Al₂O₃ and TiC, and the like. A material in which a porous SiC body is impregnated with Al is called AlSiC, and a material in which a porous SiC body is impregnated with Si is called SiSiC. It is preferable to select a material for the base plate 30 that has a thermal expansion coefficient close to that of the material for the ceramic substrate 20. For example, when the ceramic substrate 20 is made of alumina, the base plate 30 is preferably made of SiSiCTi or AlSiC, which have a thermal expansion coefficient close to that of alumina.

As shown in FIGS. 1-1 and 2-1, the upper surface 31 of the base plate 30 is bonded to the lower surface 23 of the ceramic substrate 20 via a bonding layer 40. The bonding layer 40 bonds the lower surface 23 of the ceramic substrate 20 and the upper surface 31 of the base plate 30 together. The bonding layer 40 may be configured as a metal layer made of, for example, solder or metal brazing material. The bonding layer 40 is formed, for example, by TCB (Thermal Compression Bonding). TCB is a known method in which a metal bonding material is sandwiched between two members to be bonded, and the two members are pressure-bonded while being heated to a temperature below the solidus temperature of the metal bonding material. The bonding layer 40 is not limited to a metal layer. For example, a resin bonding layer may be used instead of the metal layer. The resin bonding layer can be made of, for example, a cured product of a silicone resin adhesive, an epoxy resin adhesive, an acrylic resin adhesive, or a urethane resin adhesive.

The side walls 28a, 28b of the ceramic substrate 20, the outer periphery of the bonding layer 40, the chamfered portion 29, and at least a portion of the side surface of the base plate 30 can be covered with a coating layer 60. Examples of the coating layer 60 include a thermal spray film of alumina or yttria, an aerosol deposition film, and an ion-assisted deposition film. From the viewpoint of preventing corrosion due to plasma and reducing particle generation, the porosity of the coating layer 60 is preferably 2% or less, more preferably 1% or less, and even more preferably 0.5% or less. It is preferable to use ion-assisted deposition for the coating layer 60, since it is possible to produce a dense film with low porosity. By covering at least a portion of the side walls 28a, 28b of the ceramic substrate 20, the outer periphery of the bonding layer 40, the chamfered portion 29, and the side surface of the base plate 30 with such a dense film, corrosion of these areas by plasma can be suppressed, and the generation of particles can be reduced. In addition, the coating layer is preferably an insulating film.

In the first and second embodiments, the member 10 for semiconductor manufacturing equipment may have a plurality of holes that penetrate the member 10 for semiconductor manufacturing equipment in the vertical direction. Such holes include a plurality of gas holes 50 opening in the upper surface 21 and lift pin holes for inserting lift pins that move the wafer W up and down relative to the upper surface 21. A plurality of gas holes 50 can be provided at appropriate positions when the upper surface 21 is viewed from above (see FIGS. 1-3 and 2-3). The gas holes 50 are supplied with a thermally conductive gas such as He gas. Typically, the gas hole 50 can be provided so as to open to a portion of the upper surface 21 on which the seal band 25 and the plurality of protrusions 22 are provided, where the seal band 25 and the plurality of protrusions 22 are not provided (reference surface 21b). When the thermal conduction gas is supplied to the gas holes 50, the thermal conduction gas fills the space on the back side of the wafer W placed on the upper surface 21. A plug 55 having a gas flow path may be embedded in the gas hole 50. A plurality of lift pin holes can be provided at equal intervals along concentric circles on the upper surface 21 when the upper surface 21 is viewed in a plan view.

### <2. How to Use Member for Semiconductor Manufacturing Equipment>

Next, a method for using the member 10 for semiconductor manufacturing equipment will be described by way of example. First, with the member 10 for semiconductor manufacturing equipment installed in a chamber (not shown), a wafer W is placed on the upper surface 21 of the ceramic substrate 20. Then, the pressure inside the chamber is reduced using a vacuum pump to adjust it to a predetermined vacuum level, and a voltage is applied to the electrode 26 of the ceramic substrate 20 to generate an electrostatic adsorption force, thereby adsorbing and fixing the wafer W to the wafer mounting surface (specifically, the upper end surface 21c of the seal band 25 and the upper end surfaces 21a of the protrusions 22).

Next, the chamber is filled with a reactive gas atmosphere at a predetermined pressure (for example, several tens to several hundreds of Pa), and in this state, a high-frequency voltage such as an RF voltage is applied between an upper electrode (not shown) provided on the ceiling of the chamber and the base plate 30 of the semiconductor manufacturing equipment member 10 to generate plasma. The surface of the wafer W is processed by the generated plasma.

### <3. Manufacturing Examples of Member for Semiconductor Manufacturing Equipment>

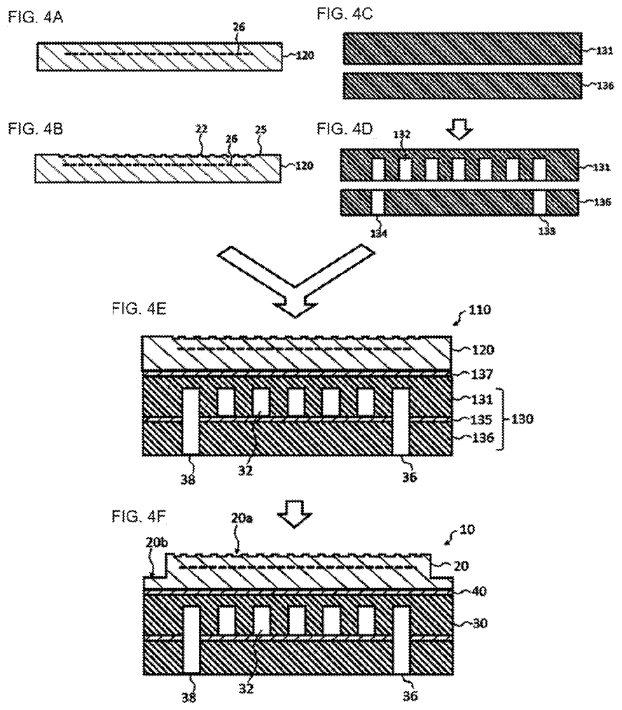

Next, an example of manufacturing the member 10 for a semiconductor manufacturing equipment will be described with reference to FIGS. 4A to 4F. Here, a manufacturing example of the member 10 for a semiconductor manufacturing equipment according to the second embodiment shown in FIG. 2-1 will be described. First, a disk-shaped ceramic sintered body 120, which is the base of the ceramic substrate 20, is prepared by hot-pressing and firing a formed body of ceramic powder (FIG. 4A). The formed body may be prepared by stacking a plurality of tape compacts, by a mold casting method, or by compressing the ceramic powder. The ceramic sintered body 120 has an electrode 26 built therein.

Next, the upper surface of the ceramic sintered body 120 is polished, and then the plurality of protrusions 22 and the seal band 25 are formed by blasting or laser processing (FIG. 4B). This allows the upper end surfaces 21a of the plurality of protrusions 22 to be smoothed. The polishing method includes lapping, but it is preferable to carry out polishing in addition to lapping. Diamond slurry can be used for lapping, and colloidal silica can be used for polishing. Further, a plurality of protrusions 22 and a seal band 25 are formed on the upper surface of the ceramic sintered plate by laser processing or the like. The timing for forming the plurality of protrusions 22 and the seal band 25 may be after the ceramic substrate 20 and the base plate 30 are bonded together.

In parallel with this, two MMC disk members 131 and 136 are fabricated (FIG. 4C). Then, grooves 132 that will eventually become the refrigerant flow paths 32 are formed in the lower surface of the upper MMC disk member 131 by machining (FIG. 4D). The lower MMC disk member 136 is provided with a through hole 133 for introducing a refrigerant and a through hole 134 for discharging the refrigerant. When the ceramic sintered body 120 is made of alumina, the MMC disk members 131 and 136 are preferably made of SiSiCTi or AISiC. This is because the thermal expansion coefficient of alumina is roughly the same as that of SiSiCTi or AISiC.

The SiSiCTi disk member can be prepared, for example, as follows: First, silicon carbide, metallic Si, and metallic Ti are mixed together to prepare a powder mixture. Next, the obtained powder mixture is subjected to uniaxial pressing to produce a disk-shaped compact, and the compact is hot-press sintered in an inert atmosphere to obtain a SiSiCTi disk member.

Next, a metal bonding material 135 is placed between the lower surface of the upper MMC disk member 131 and the upper surface of the lower MMC disk member 136, and a metal bonding material 137 is placed on the upper surface of the upper MMC disk member 131. Then, the ceramic sintered body 120 is placed on the metal bonding material 137 arranged on the top surface of the upper MMC disk member 131. This results in a laminate 110 in which the lower MMC disk member 136, metal bonding material 135, upper MMC disk member 131, metal bonding material 137, and ceramic sintered body 120 are laminated in this order from the bottom (FIG. 4E). This laminate 110 is pressed while being heated (TCB) to obtain a bonded body. The bonded body is formed by bonding a ceramic sintered body 120 to the upper surface of an MMC block 130, which is the base of the base plate 30, via a metal bonding layer. The MMC block 130 is formed by bonding an upper MMC disk member 131 and a lower MMC disk member 136 via a metal bonding layer. The MMC block 130 has a refrigerant flow path 32, a refrigerant inlet 36, and a refrigerant outlet 38.

The TCB is performed, for example, as follows. That is, the laminate is pressed and bonded at a temperature not higher than the solidus temperature of the metal bonding material (for example, a temperature equal to or higher than the solidus temperature minus 20° C. but not higher than the solidus temperature), and then returned to room temperature. This causes the metal bonding material to become a metal bonding layer. In this case, an Al—Mg based bonding material or an Al—Si—Mg based bonding material can be used as the metal bonding material. For example, when TCB is performed using an Al—Si—Mg based bonding material, the laminate is pressurized while being heated in a vacuum atmosphere. It is preferable to use a metal bonding material having a thickness of about 100 μm.

In the above description, the base plate 30 is made of MMC and is bonded to the ceramic sintered body 120 via the metal bonding material 137. Alternatively, the base plate 30 may be made of metal and bonded to the ceramic sintered body 120 using a resin adhesive sheet.

Furthermore, when the bonding layer 40 is formed using the metal bonding material 137, the coating layer 60 can be formed by thermal spraying onto the base plate 30 either before or after bonding with the ceramic substrate 20. When the bonding layer 40 is formed using a resin adhesive sheet, the resin melts, so the coating layer 60 is formed by thermal spraying before bonding to the ceramic substrate 20.

Next, the outer periphery of the ceramic sintered body 120 is cut to form a step, thereby forming a ceramic substrate 20 having a central portion 20a and an outer peripheral portion 20b. Next, the surface of the side wall 28b of the central portion 20a, preferably the surface of the side wall 28b of the central portion 20a and the surface of the chamfered portion 29, are smoothed. As a method for smoothing, polishing using a machining center with a fine grinding stone or wet blasting can be adopted. As a result, the member for semiconductor manufacturing equipment 10 is obtained (FIG. 4F).

It should be noted that, although the base plate 30 in FIG. 1-1 is described as a single unit, it may have a structure in which two members are bonded by a metal bonding layer as shown in FIG. 4F, or a structure in which three or more members are bonded by a metal bonding layer.

### Examples

### (1-1. Manufacture of Ceramic Substrate)

A ceramic sintered body in the shape of a disk (diameter 300 mm×thickness 4 mm) was prepared by hot-pressing and sintering a formed body of alumina powder. Next, the top surface and side wall of the ceramic sintered body were machined by grinding and polishing to adjust the shape, and then a C-chamfered portion was created at the corner where the side wall and top surface were connected by grinding. Thereafter, the surface of the side wall and the C-chamfered portion of the ceramic sintered body were subjected to a smoothing treatment, respectively. The smoothing treatment can be carried out by polishing with a grindstone, polishing by wet blasting or dry blasting, polishing with a brush using diamond slurry, or the like. In addition, these may be combined to gradually increase the grit number of the grindstone. Here, a stepwise smoothing treatment was also carried out, but the grit number of the grindstone was adjusted so that the arithmetic mean roughness Ra of the surface of the side wall of the ceramic substrate would be the value shown in Table 1 according to the test number. As mentioned above, the arithmetic mean roughness Ra was measured in accordance with JIS B0601: 2013. Although the arithmetic mean roughness Ra of the C-chamfered portion was not measured, it is presumed to be similar to that of the side wall surface since the smoothing treatment conditions were the same. After the smoothing treatment, the processed surface was washed with an organic solvent and pure water.

### (1-2. Evaluation of Particle Suppression Effect)

Particles are often caused by ceramic processing residues or fractured layers (microcracks) remaining on the surface of the side walls or chamfered portions of the ceramic substrate. Such processing residues and fractured layers (microcracks) tend to adhere to the adhesive tape. Thus, the particle suppression effect can be easily evaluated by applying and peeling off adhesive tape without actually placing a ceramic substrate under the influence of plasma. Accordingly, in this test, cellophane tape was applied to the surface of the side wall under the following conditions and then peeled off.

### <Conditions for Applying and Peeling Cellophane Tape>

Type of cellophane tape: Nichiban Co., Ltd. Cellotape (Registered trademark) No. 405 Cellophane tape application area to side wall: 100 mm²
Pressure applied when applying cellophane tape to side wall: 98,066 Pa
Speed when peeling cellophane tape from side wall: 1 mm/s
Angle when peeling cellophane tape from side wall: 30°

The likelihood of particle generation was evaluated based on the number of Al₂O₃ particles adhering to the cellophane tape when peeled off. The number of Al₂O₃ particles was evaluated by enlarging the adhesive surface of the cellophane tape at a magnification of 100 times with an SEM, then binarizing it to regard the white areas as Al₂O₃ particles, and counting the number of Al₂O₃ particles with a circle equivalent diameter of 1 μm or more. The results are shown in Table 1. It can be seen that the number of adhered Al₂O₃ particles is significantly reduced when Ra is 0.4 μm or less.

TABLE 1

| | | Number of Al₂O₃ particles |
|---|---|---|
| Test | Ra | adhered to tape |
| No. | [μm] | [pcs] |
| 1 | 0.7 | 387 |
| 2 | 0.5 | 114 |
| 3 | 0.4 | 30 |
| 4 | 0.1 | 0 |

### (2-1. Manufacture of Ceramic Substrate)

A ceramic sintered body in the shape of a disk (diameter 300 mm thickness 4 mm) was prepared by hot-pressing and sintering a formed body of alumina powder. Next, the top surface and side wall of the ceramic sintered body were machined by grinding and polishing to adjust the shape, and then a C-chamfered portion was created at the corner where the side wall and top surface were connected by grinding. Thereafter, the surface of the side wall and the C-chamfered portion of the ceramic sintered body were subjected to a smoothing treatment, respectively. The smoothing treatment can be carried out by polishing with a grindstone, polishing by wet blasting or dry blasting, polishing with a brush using diamond slurry, or the like. In addition, these may be combined to gradually increase the grit number of the grindstone. Here, a stepwise smoothing treatment was also carried out, but the grit number of the grindstone was adjusted so that the arithmetic mean roughness Ra of the side wall surface of the ceramic substrate, the arithmetic mean height Sa of the side wall surface of the ceramic substrate, and the valley void volume Vvv of the side wall surface were the values listed in Table 2 according to the test number. As mentioned above, the arithmetic mean roughness Ra was measured in accordance with JIS B0601: 2013. As described above, the arithmetic mean height Sa and the valley void volume Vvv were measured in accordance with ISO 25178 using a non-contact roughness meter, Model VK-X3100, manufactured by Keyence Corporation. Although the arithmetic mean roughness Ra, arithmetic mean height Sa and valley void volume Vvv of the C-chamfered portion were not measured, they are presumed to be similar to those of the side wall surface since the smoothing treatment conditions were the same. After the smoothing treatment, the processed surface was washed with an organic solvent and pure water.

### (2-2. Evaluation of Particle Suppression Effect)

Particles are often caused by ceramic processing residues or fractured layers (microcracks) remaining on the surface of the side walls or chamfered portions of the ceramic substrate. Such processing residues and fractured layers (microcracks) tend to adhere to the adhesive tape. Thus, the particle suppression effect can be easily evaluated by applying and peeling off adhesive tape without actually placing a ceramic substrate under the influence of plasma. Accordingly, in this test, cellophane tape was applied to the surface of the side wall under the following conditions and then peeled off.

### <Conditions for Applying and Peeling Cellophane Tape>

Type of cellophane tape: Nichiban Co., Ltd. Cellotape (Registered trademark) No. 405
Cellophane tape application area to side wall: 100 mm²
Pressure applied when applying cellophane tape to side wall: 98,066 Pa
Speed when peeling cellophane tape from side wall: 1 mm/s
Angle when peeling cellophane tape from side wall: 30°

The likelihood of particle generation was evaluated based on the number of Al₂O₃ particles adhering to the cellophane tape when peeled off. The number of Al₂O₃ particles was evaluated by enlarging the adhesive surface of the cellophane tape at a magnification of 100 times with an SEM, then binarizing it to regard the white areas as Al₂O₃ particles, and counting the number of Al₂O₃ particles with a circle equivalent diameter of 1 μm or more. The results are shown in Table 2. The smaller the Ra is, the more likely it is that the number of adhered Al₂O₃ particles will decrease. However, even if the Ra is the same, it can be seen that the number of adhered Al₂O₃ particles varies significantly by changing Sa, Vvv, and their standard deviations.

TABLE 2

| | | | Sa standard | | Vw standard | | Number of Al₂O₃ |
|---|---|---|---|---|---|---|---|
| | | Sa | deviation | Vw | deviation | Ra | particles adhered to |
| Test No. | | [μm] | [μm] | [ml/m²] | [ml/m²] | [μm] | tape |
| 1 | Example | 1.3 | 0.20 | 0.60 | 0.10 | 0.4 | 150 |
| 2 | Example | 1.0 | 0.14 | 0.50 | 0.12 | 0.4 | 120 |
| 3 | Example | 1.0 | 0.10 | 0.20 | 0.10 | 0.4 | 98 |
| 4 | Example | 1.0 | 0.05 | 0.12 | 0.03 | 0.4 | 83 |
| 5 | Example | 0.3 | 0.05 | 0.04 | 0.01 | 0.4 | 20 |
| 8 | Example | 0.3 | 0.005 | 0.04 | 0.005 | 0.4 | 10 |
| 7 | Example | 0.2 | 0.05 | 0.04 | 0.01 | 0.2 | 3 |
| 8 | Example | 0.2 | 0.005 | 0.04 | 0.005 | 0.2 | 0 |

### (3-1. Manufacture of Ceramic Substrate)

A ceramic sintered body in the shape of a disk (diameter 300 mm×thickness 4 mm) was prepared by hot-pressing and sintering a formed body of alumina powder. Next, the top surface and side wall of the ceramic sintered body were machined by grinding and polishing to adjust the shape, and then a C-chamfered portion was created at the corner where the side wall and top surface were connected by grinding. Thereafter, the surface of the side wall and the C-chamfered portion of the ceramic sintered body were subjected to a smoothing treatment, respectively. The smoothing treatment can be carried out by polishing with a grindstone, polishing by wet blasting or dry blasting, polishing with a brush using diamond slurry, or the like. In addition, these may be combined to gradually increase the grit number of the grindstone. Here, a stepwise smoothing treatment was also carried out, but the grit number of the grindstone was adjusted so that the arithmetic mean height Sa₁ of the surface of the side wall of the ceramic substrate and the arithmetic mean height Sa₄ of the surface of the C-chamfered portion of the ceramic substrate were the values shown in Table 3 according to the test number. As described above, the arithmetic mean height Sa was measured in accordance with ISO 25178 using a non-contact roughness meter, Model VK-X3100, manufactured by Keyence Corporation. After the smoothing treatment, the processed surface was washed with an organic solvent and pure water.

### (3-2. Evaluation of Particle Suppression Effect)

Particles are often caused by ceramic processing residues or fractured layers (microcracks) remaining on the surface of the side walls or chamfered portions of the ceramic substrate. Such processing residues and fractured layers (microcracks) tend to adhere to the adhesive tape. Thus, the particle suppression effect can be easily evaluated by applying and peeling off adhesive tape without actually placing a ceramic substrate under the influence of plasma. Accordingly, in this test, cellophane tape was applied to the surface of the side wall under the following conditions and then peeled off.

### <Conditions for Applying and Peeling Cellophane Tape>

Type of cellophane tape: Nichiban Co., Ltd. Cellotape (registered trademark) No. 405
Cellophane tape application area to side wall: 100 mm²
Pressure applied when applying cellophane tape to side wall: 98,066 Pa
Speed when peeling cellophane tape from side wall: 1 mm/s
Angle when peeling cellophane tape from side wall: 30°

The likelihood of particle generation was evaluated based on the number of Al₂O₃ particles adhering to the cellophane tape when peeled off. The number of Al₂O₃ particles was evaluated by enlarging the adhesive surface of the cellophane tape at a magnification of 100 times with an SEM, then binarizing it to regard the white areas as Al₂O₃ particles, and counting the number of Al₂O₃ particles with a circle equivalent diameter of 1 μm or more. The results are shown in Table 3. It can be seen that when Sa₁ is 1.1 μm or less, the number of adhered Al₂O₃ particles is significantly reduced. It can also be seen that even if Sa₁ is the same, the smaller the standard deviation, the smaller the number of adhered Al₂O₃ particles. Furthermore, it has been revealed that it is preferable for the C-chamfered portion to be smooth. A smooth C-chamfered portion reduces the amount of Al₂O₃ remaining in the C-chamfered portion, and even if Al₂O₃ particles shed from the C-chamfered portion, they are less likely to adhere to the side wall.

TABLE 3

| | | | | | | Number |
|---|---|---|---|---|---|---|
| | | | Sₐ₁ | | Sₐ₄ | of Al₂O₃ |
| | | | standard | | standard | particles |
| Test | | Sₐ₁ | deviation | Sₐ₄ | deviation | adhered to |
| No. | | [μm] | [μm] | [μm] | [ml/m²] | tape |
| 9 | Comparative | 1.4 | 0.50 | 0.50 | 0.50 | 360 |
| | Example | | | | | |
| 10 | Comparative | 1.2 | 0.20 | 0.50 | 0.20 | 270 |
| | Example | | | | | |
| 11 | Example | 1.1 | 0.10 | 0.12 | 0.10 | 120 |
| 12 | Example | 1.1 | 0.10 | 0.08 | 0.05 | 85 |
| 13 | Example | 0.5 | 0.05 | 0.06 | 0.05 | 76 |
| 14 | Example | 0.5 | 0.02 | 0.06 | 0.02 | 30 |
| 15 | Example | 0.3 | 0.005 | 0.06 | 0.01 | 0 |
| 16 | Example | 0.2 | 0.005 | 0.05 | 0.005 | 0 |

### DESCRIPTION OF REFERENCE NUMERALS

10: Member for semiconductor manufacturing equipment
20: Ceramic substrate
20a: Central portion
20b: Outer peripheral portion
21: Top surface
21a: Top end surface
21b: Reference surface
21c: Top end surface
22: Protrusion
23: Lower surface
25: Seal band
26: Electrode
27: Upper surface
28a: Side wall
28b: Side wall
29: Chamfered portion
30: Base plate
31: Top surface
32: Refrigerant flow path
36: Refrigerant inlet
38: Refrigerant outlet
40: Bonding layer
50: Gas hole
55: Plug
60: Coating layer
110: Laminate
120: Ceramic sintered body
130: MMC block
131: Disk member
132: Groove
133: Through hole
134: Through hole
135: Metal bonding material
136: Disk member
137: Metal bonding material
W: Wafer
FR: Focus ring

1. A member for semiconductor manufacturing equipment comprising a ceramic substrate, the ceramic substrate comprising: an upper surface having a plurality of protrusions for placing a wafer thereon and a side wall forming an outer edge of the upper surface, wherein an arithmetic mean roughness Ra₁ of a surface of the side wall is 0.4 μm or less and the surface of the side wall has patterned irregularities.

2. The member for semiconductor manufacturing equipment according to claim 1,
wherein the patterned irregularities are formed by laser processing.

3. The member for semiconductor manufacturing equipment according to claim 1, wherein the surface of the side wall has one or more of the following patterned irregularities i) to iv):
i) A pattern composed of a plurality of streak-like convex portions
ii) A pattern composed of a plurality of dot-like convex portions
iii) A pattern composed of a plurality of dimples
iv) A pattern composed of mesh-like convex portions in which a plurality of linear convex portions intersect.

4. The member for semiconductor manufacturing equipment according to claim 1, wherein the upper surface and the side wall are connected via a chamfered portion, and an arithmetic mean roughness Ra₄ of the surface of the chamfered portion is 0.4 μm or less.

5. The member for semiconductor manufacturing equipment according to claim 1, wherein either or both of the following are satisfied:
an arithmetic mean height Sa₁ of the surface of the side wall is 1.1 μm or less;
a valley void volume Vᵥᵥ₁ of the surface of the side wall is 0.5 ml/m² or less.

6. The member for semiconductor manufacturing equipment according to claim 4, wherein either or both of the following are satisfied:
an arithmetic mean height Sa₄ of the surface of the chamfered portion is 1.1 μm or less;
a valley void volume Vᵥᵥ₄ of the surface of the chamfered portion is 0.5 ml/m² or less.

7. The member for semiconductor manufacturing equipment according to claim 5, wherein either or both of the following are satisfied:
a standard deviation of the arithmetic mean height Sa₁ of the surface of the side wall is 0.1 μm or less;
a standard deviation of the valley void volume Vᵥᵥ₁ of the surface of the side wall is 0.1 ml/m² or less.

8. The member for semiconductor manufacturing equipment according to claim 6, wherein either or both of the following are satisfied:
a standard deviation of the arithmetic mean height Sa₄ of the surface of the chamfered portion is 0.1 μm or less;
a standard deviation of the valley void volume Vᵥᵥ₄ of the surface of the chamfered portion is 0.1 ml/m² or less.

9. The member for semiconductor manufacturing equipment according to claim 1, wherein the arithmetic mean roughness Ra₁ of the surface of the side wall is smaller when measured in a circumferential direction of the ceramic substrate than when measured in a thickness direction of the ceramic substrate.

10. The member for semiconductor manufacturing equipment according to claim 1, wherein at least a portion of the side wall is covered with a coating layer, and a porosity of the coating layer is 2% or less.

11. A member for semiconductor manufacturing equipment comprising a ceramic substrate, the ceramic substrate comprising:
a central portion upper surface having a plurality of protrusions for placing a wafer thereon;
an outer peripheral portion upper surface located on an outer peripheral side of the central portion upper surface and lower than the central portion upper surface; and
a central portion side wall defining a step between the central portion upper surface and the outer peripheral portion upper surface;
wherein an arithmetic mean roughness Ra₁ of a surface of the central portion side wall is smaller than an arithmetic mean roughness Ra₂ of the outer peripheral portion upper surface, and the arithmetic mean roughness Ra₁ of the surface of the central portion side wall is greater than an arithmetic mean roughness Ra₃ of an upper end surface of the plurality of protrusions.

12. The member for semiconductor manufacturing equipment according to claim 11, wherein the arithmetic mean roughness Ra₁ of the surface of the central portion side wall is 0.4 μm or less.

13. The member for semiconductor manufacturing equipment according to claim 11, wherein the central portion upper surface and the central portion side wall are connected via a chamfered portion.

14. The member for semiconductor manufacturing equipment according to claim 13, wherein an arithmetic mean roughness Ra₄ of a surface of the chamfered portion is smaller than the arithmetic mean roughness Ra₂ of the outer peripheral portion upper surface.

15. The member for semiconductor manufacturing equipment according to claim 13, wherein an arithmetic mean roughness Ra₄ of a surface of the chamfered portion is 0.4 μm or less.

16. The member for semiconductor manufacturing equipment according to claim 13, wherein an absolute value of a difference between an arithmetic mean roughness Ra₄ of a surface of the chamfered portion and the arithmetic mean roughness Ra₁ of the surface of the central portion side wall is 0.4 μm or less.

17. A member for semiconductor manufacturing equipment comprising a ceramic substrate, the ceramic substrate comprising:
a central portion upper surface having a plurality of protrusions for placing a wafer thereon;
an outer peripheral portion upper surface located on an outer peripheral side of the central portion upper surface and lower than the central portion upper surface; and
a central portion side wall defining a step between the central portion upper surface and the outer peripheral portion upper surface;
wherein an arithmetic mean roughness Ra₁ of a surface of the central portion side wall is smaller than an arithmetic mean roughness Ra₂ of the outer peripheral portion upper surface,
the central portion upper surface and the central portion side wall are connected via a chamfered portion, and
an arithmetic mean roughness Ra₄ of a surface of the chamfered portion is greater than an arithmetic mean roughness Ra₃ of an upper end surface of the plurality of protrusions.

18. A member for semiconductor manufacturing equipment comprising a ceramic substrate, the ceramic substrate comprising:
a central portion upper surface having a plurality of protrusions for placing a wafer thereon;
an outer peripheral portion upper surface located on an outer peripheral side of the central portion upper surface and lower than the central portion upper surface; and
a central portion side wall defining a step between the central portion upper surface and the outer peripheral portion upper surface;
wherein an arithmetic mean roughness Ra₁ of a surface of the central portion side wall is smaller than an arithmetic mean roughness Ra₂ of the outer peripheral portion upper surface, and
the surface of the central portion side wall has patterned irregularities.

19. The member for semiconductor manufacturing equipment according to claim 18, wherein the patterned irregularities are formed by laser processing.

20. The member for semiconductor manufacturing equipment according to claim 18, wherein the surface of the central portion side wall has one or more patterned irregularities selected from the following i) to iii):
i) A pattern composed of a plurality of dot-like convex portions
ii) A pattern composed of a plurality of dimples
iii) A pattern composed of mesh-like convex portions in which a plurality of linear convex portions intersect.

21. The member for semiconductor manufacturing equipment according to claim 18, wherein the arithmetic mean roughness Ra₁ of the surface of the central portion side wall is 0.4 μm or less.

22. The member for semiconductor manufacturing equipment according to claim 11, wherein at least a portion of the central portion side wall is covered with a coating layer, and a porosity of the coating layer is 2% or less.
